(19) United States
(12) Patent Application Publication
(10) Pub. No.: US 2024/0256919 A1
(43) Pub. Date: Aug. 1, 2024

(54) INFORMATION PROCESSING APPARATUS, METHOD FOR IDENTIFYING MACHINE DIFFERENCE, AND HEAT TREATMENT APPARATUS

(71) Applicant: Tokyo Electron Limited, Tokyo (JP)

(72) Inventors: Yusuke TSUCHIYA, Hokkaido (JP); Masakazu YAMAMOTO, Iwate (JP); Hiroyuki KARASAWA, Yamanashi (JP)

(21) Appl. No.: 18/425,060

(22) Filed: Jan. 29, 2024

(30) Foreign Application Priority Data
Jan. 31, 2023 (JP) 2023-013092

(51) Int. Cl. G06N 5/022

(52) U.S. Cl. CPC G06N 5/022

(57) ABSTRACT

An information processing apparatus that identifies a machine difference in a heat treatment apparatus for heat-treating a processing target substrate includes a time series data acquisition unit that acquires time series data regarding temperature behavior of heat treatment apparatuses that have executed a recipe, a time series data prediction unit that predicts time series data regarding temperature behavior of the heat treatment apparatuses that have executed the recipe, using an ideal virtual model of the heat treatment apparatuses, a difference data calculation unit that calculates difference data between the acquired time series data and the predicted time series data for each of the heat treatment apparatuses, an adjustment unit that adjusts a parameter of the virtual model for each heat treatment apparatus, using the difference data, and a machine difference identification unit that identifies the machine difference candidate parameter based on a change in the parameter before and after adjustment.

### CROSS-REFERENCE TO RELATED APPLICATIONS

The present application is based on and claims priority from Japanese Patent Application No. 2023-013092, filed on Jan. 31, 2023, with the Japan Patent Office, the disclosure of which is incorporated herein in its entirety by reference.

### TECHNICAL FIELD

The present disclosure relates to an information processing apparatus, a method for identifying a machine difference, and a heat treatment apparatus.

### BACKGROUND

In a heat treatment apparatus, for example, even if the power supplied to the heater is the same, a difference in temperature distribution occurs in the height direction inside a processing container due to the presence of a machine difference that is a difference between components of the heat treatment apparatus. Conventionally, to stabilize the results of heat treatment, there is a known technology to correct the machine difference in the heat treatment apparatus and to achieve uniformity in temperature distribution along the height direction inside the processing container (see, e.g., Japanese Patent Laid-Open Publication No. 2022-168572).

### SUMMARY

According to an aspect of the present disclosure, there is provided an information processing apparatus that identifies a machine difference in a heat treatment apparatus for heat-treating a processing target substrate. The information processing apparatus includes a time series data acquisition unit that acquires time series data regarding temperature behavior of a plurality of heat treatment apparatuses that have executed a recipe, a time series data prediction unit that predicts time series data regarding temperature behavior of each of the plurality of heat treatment apparatuses that has executed the recipe, using an ideal virtual model of the heat treatment apparatus, a difference data calculation unit that calculates difference data between the acquired time series data and the predicted time series data for each of the plurality of heat treatment apparatuses, an adjustment unit that adjusts a parameter of the virtual model for each of the plurality of heat treatment apparatuses, using the difference data, and a machine difference identification unit that identifies the machine difference candidate parameter based on a change in the parameter before and after adjustment for each of the plurality of heat treatment apparatuses.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a longitudinal cross-sectional view schematically illustrating a heat treatment apparatus according to the embodiment.

FIG. 2 is a cross-sectional view schematically illustrating a configuration of a heat treatment furnace.

FIG. 3 is a diagram illustrating an example of a configuration of an information processing system according to the embodiment.

FIG. 4 is a diagram illustrating an example of a hardware configuration of a computer.

FIG. 5 is a diagram illustrating an example of a functional configuration of a control unit of the heat treatment apparatus according to the embodiment.

FIG. 6 is a diagram illustrating an example of a functional configuration of an analysis server according to the embodiment.

FIG. 7 is a flowchart illustrating an example of a processing procedure of the information processing system according to the embodiment.

FIG. 8 is a flowchart illustrating an example of a processing procedure of identifying a machine difference candidate.

FIGS. 9A to 9C are diagrams illustrating an example of a processing of identifying a machine difference candidate.

FIGS. 10A and 10B are diagrams illustrating an example of a display image presented to an operator.

FIG. 11 is a diagram illustrating an example of a configuration of a table that corresponds parameters of an ideal virtual model to components of the heat treatment apparatus.

FIG. 12 is a diagram illustrating an example of a configuration of a table that corresponds correspondence to the machine difference candidate.

FIG. 13 is a longitudinal cross-sectional view schematically illustrating the heat treatment apparatus according to the embodiment.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to the drawings.

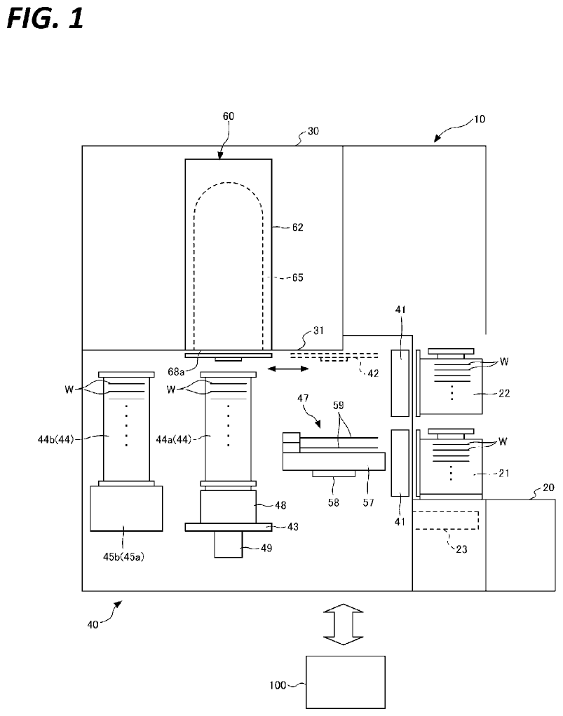

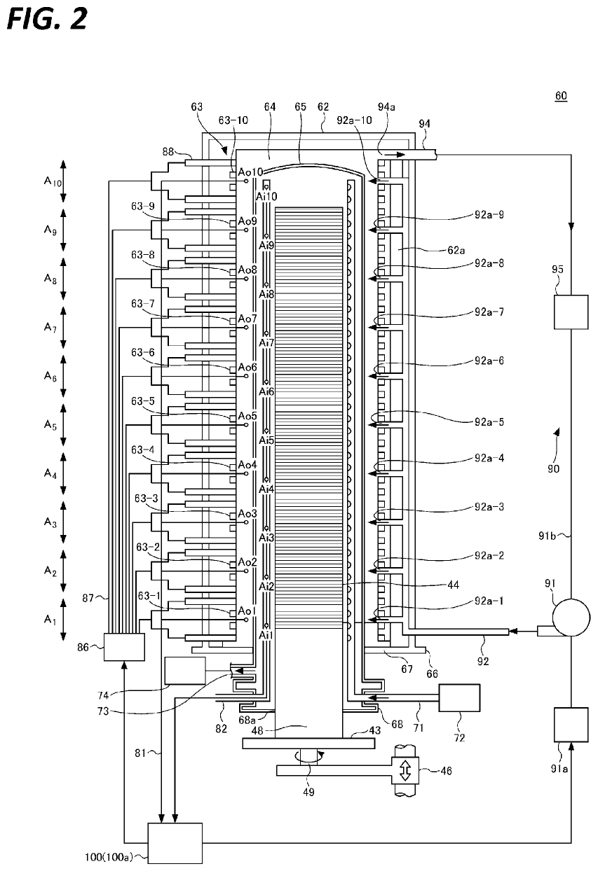

FIG. 1 is a longitudinal cross-sectional view schematically illustrating a heat treatment apparatus according to the embodiment. FIG. 2 is a cross-sectional view schematically illustrating a configuration of a heat treatment furnace.

The heat treatment apparatus 10 includes a vertical-type heat treatment furnace 60, in which wafers W may be held and accommodated in a boat at predetermined intervals along the vertical direction and may be subjected to various types of heat treatment such as oxidation, diffusion, and reduced-pressure CVD. In the following, an example for heat-treating the surface of the wafer W provided in a processing container 65 by supplying a gas into the processing container 65 will be described. The wafer W is an example of a processing target substrate. The processing target substrate is not limited to the circular wafer W.

The heat treatment apparatus 10 of FIG. 1 includes a stage 20, a housing 30, and a control unit 100. The stage 20 is, for example, a load port. The stage 20 is provided at the front of the housing 30. The housing 30 contains a loading area 40 and the heat treatment furnace 60.

The loading area 40 is, for example, a work area. The loading area 40 is located below inside the housing 30. The heat treatment furnace 60 is located above the loading area 40 inside the housing 30. Further, a base plate 31 is provided between the loading area 40 and the heat treatment furnace 60.

The stage 20 is for loading and unloading the wafer W into and from the housing 30. Storage containers 21 and 22 are placed on the stage 20. The storage containers 21 and 22 are sealed storage containers (hoops) each having a detachable lid (not illustrated) on the front side, which may accommodate a plurality of (e.g., about 25) wafers W at predetermined intervals.

Further, an alignment device (aligner) 23 may be provided below the stage 20 to align, in one direction, cutouts (e.g., notches) provided on the outer periphery of the wafers W transferred by a transfer mechanism 47.

The loading area 40 is for transferring the wafers W between the storage containers 21 and 22 and a boat 44 to carry (load) the boat 44 into the processing container 65 and carry (unload) the boat 44 out of the processing container 65. The loading area 40 is provided with a door mechanism 41, a shutter mechanism 42, a lid body 43, the boat 44, a base 45a, a base 45b, a lifting mechanism 46 in FIG. 2, and the transfer mechanism 47.

The door mechanism 41 opens the storage containers 21 and 22 to communicate the inside of the storage containers 21 and 22 with the loading area 40 by removing the lids of the storage containers 21 and 22. The shutter mechanism 42 is located above the loading area 40. The shutter mechanism 42 is provided to cover (or block) a furnace opening 68a, in order to reduce or prevent heat inside the high-temperature furnace from being released from the furnace opening 68a to the loading area 40, when the lid body 43 is open.

The lid body 43 includes a warming cylinder 48 and a rotation mechanism 49. The warming cylinder 48 is provided on the lid body 43. The warming cylinder 48 is for preventing the boat 44 from being cooled by heat transfer with the lid body 43 side and keeping the boat 44 warm. The rotation mechanism 49 is attached to the underside of the lid body 43. The rotation mechanism 49 is for rotating the boat 44. A rotating shaft of the rotation mechanism 49 is positioned to airtightly pass through the lid body 43 and to rotate a rotary table disposed on the lid body 43.

The lifting mechanism 46 is driven to raise and lower the lid body 43 when loading and unloading the boat 44 from the loading area 40 into and out of the processing container 65. When the boat 44 is raised and loaded into the processing container 65 by the lifting mechanism 46, the lid body 43 is brought into contact with the furnace opening 68a to seal the furnace opening 68a.

The boat 44 placed on the lid body 43 may rotatably hold the wafer W in a horizontal plane inside the processing container 65. In addition, the heat treatment apparatus 10 may include a plurality of boats 44. The loading area 40 is provided with boats 44a and 44b.

The loading area 40 is provided with the bases 45a and 45b and a boat transfer mechanism. The bases 45a and 45b are stages onto which the boats 44a and 44b are transferred from the lid body 43, respectively. The boat transfer mechanism is for transferring the boat 44a or 44b from the lid body 43 to the base 45a or 45b.

The boats 44a and 44b are made of, for example, quartz, and are used to mount the wafers W having a large diameter (e.g., a diameter of 300 mm) in a horizontal state at predetermined intervals (pitch width) in the vertical direction. The boats 44a and 44b are provided with a plurality of (e.g., three) pillars between a ceiling plate and a bottom plate. The pillars are provided with claw portions for holding the wafers W. Further, the boats 44a and 44b may be provided with auxiliary pillars as appropriate together with the pillars.

The transfer mechanism 47 is used to transfer the wafer W between the storage container 21 or 22 and the boat 44a or 44b. The transfer mechanism 47 includes a base 57, a lifting arm 58, and a plurality of forks (transfer plates) 59. The base 57 is provided to enable lifting and pivoting thereof. The lifting arm 58 is provided to be vertically movable (raised and lowered) using a ball screw or others. The base 57 is attached to the lifting arm 58 in a horizontally pivotable manner.

FIG. 2 is a cross-sectional view illustrating a schematic configuration of the heat treatment furnace. The heat treatment furnace 60 in FIG. 2 is an example of a vertical-type furnace for accommodating a plurality of thin disk-shaped wafers W and performing predetermined heat treatment thereon. The heat treatment furnace 60 includes a jacket 62, a heater 63, a space 64, and the processing container 65.

The processing container 65 is for accommodating and heat-treating the wafer W held in the boat 44. The processing container 65 is made of, for example, quartz, and has a vertically long shape. The processing container 65 is supported by a base plate 66 via a lower manifold 68. A gas is supplied from the manifold 68 to the processing container 65 via an injector 71. The injector 71 supplies the gas from a jet outlet (hole) into the processing container 65. The injector 71 is connected to a gas source 72. Further, the gas supplied to the processing container 65 is exhausted from an exhaust system 74, which includes a vacuum pump capable of controlling pressure reduction through an exhaust port 73.

The lid body 43 closes the furnace opening 68a at the bottom of the manifold 68 when the boat 44 is loaded into the processing container 65. The lid body 43 is provided to be able to be raised and lowered by the lifting mechanism 46. The warming cylinder 48 is placed on the top of the lid body 43. The boat 44 in which a plurality of wafers W are mounted at predetermined intervals in the vertical direction is placed on the top of the warming cylinder 48.

The jacket 62 is provided to cover the periphery of the processing container 65 and also defines the space 64 around the processing container 65. The jacket 62 has a cylindrical shape, like the processing container 65. The jacket 62 is supported by the base plate 66. A thermal insulator 62a, which is made of, for example, glass wool, may be provided inside the jacket 62 and outside the space 64.

The heater 63 is provided to cover the periphery of the processing container 65. For example, the heater 63 is provided inside the jacket 62 and outside the space 64. The heater 63 is used to heat not only the processing container 65 but also the wafer W held in the boat 44, i.e., the wafer W inside the processing container 65. The heater 63 functions as a heating device that heats the inside of the processing container 65.

Further, the heater 63 includes a heating resistor such as a carbon wire. The heater 63 is capable of controlling the temperature of the gas flowing inside the space 64 as well as heating the inside of the processing container 65 to a predetermined temperature (e.g., 50° C. to 1,200° C.).

The space 64 and the space inside the processing container 65 are divided into a plurality of unit areas, for example, 10 unit areas A1, A2, A3, A4, A5, A6, A7, A8, A9 and A10 in the vertical direction. The heater 63 is divided into heaters 63-1, 63-2, 63-3, 63-4, 63-5, 63-6, 63-7, 63-8, 63-9 and 63-10 to correspond to any one of the unit areas along the vertical direction.

Each of the heaters 63-1 to 63-10 is configured to be able to independently control heating corresponding to each of the unit areas A1 to A10 by power (heater power), which is an output signal of a heater output 86 including, for example, a thyristor. The heaters 63-1 to 63-10 are an example of heating elements.

In addition, FIG. 2 illustrates an example of the space 64 and the space inside the processing container 65 divided into 10 unit areas along the vertical direction, but the number of unit areas divided is not limited to 10, and the space 64 and the space inside the processing container 65 may be divided in a number other than 10. Further, FIG. 2 illustrates equitable division, but the present disclosure is not limited thereto, and smaller divided areas may be designated around the furnace opening 68a where a significant change in temperature is observed. The heaters 63-1 to 63-10 need only be provided at different positions along the vertical direction, respectively, and need not be provided in a one-to-one correspondence with each of the unit areas A1 to A10.

Heater temperature sensors Ao1 to Ao10 are provided as outer T/Cs in the space 64 to measure the temperature corresponding to each of the unit areas A1 to A10. Further, processing container internal temperature sensors Ai1 to Ai10 are provided as inner T/Cs in the space inside the processing container 65 to measure the temperature corresponding to each of the unit areas A1 to A10. The heater temperature sensors Ao1 to Ao10 and the processing container internal temperature sensors Ai1 to Ai10 measure the temperatures in order to measure the temperature distribution along the vertical direction. The temperature measured by the processing container internal temperature sensors Ai1 to Ai10 is an example of the measured temperature inside the processing container 65.

Measurement signals from the heater temperature sensors Ao1 to Ao10 are input to the control unit 100 via lines 81, respectively. Measurement signals from the processing container internal temperature sensors Ai1 to Ai10 are input to the control unit 100 via lines 82, respectively. The control unit 100, to which the measurement signals are input, controls heater power that is supplied from the heater output 86 to the heaters 63-1 to 63-10 based on a set temperature to be described later. The heater output 86 supplies the heater power to each of the heaters 63-1 to 63-10 via a heater output line 87 and a heater terminal 88 in response to a control signal output from the control unit 100.

Further, the heat treatment furnace 60 may include a cooling mechanism 90 for cooling the processing container 65. The cooling mechanism 90 includes, for example, a blowing device 91, a blowing pipe 92, and an exhaust pipe 94. The cooling mechanism 90 is an example of a cooler that cools the inside of the processing container 65. The cooling mechanism 90 may be a rapid cooling unit (RCU).

The blowing device 91 is, for example, a blower. The blowing device 91 blows a cooling gas composed of, for example, air into the space 64, where the heater 63 is provided, to cool the processing container 65. The blowing pipe 92 sends the cooling gas from the blowing device 91 to the space 64. The blowing pipe 92 is connected to each of jet holes 92a-1 to 92a-10, and supplies the cooling gas to the space 64.

The exhaust pipe 94 is for discharging the air inside the space 64. The space 64 is provided with an exhaust port 94a for exhausting the cooling gas from the space 64. The exhaust pipe 94 has one end connected to the exhaust port 94a.

Further, as illustrated in FIG. 2, the heat treatment furnace 60 may include a heat exchanger 95 provided in the middle of the exhaust pipe 94, and the other end of the exhaust pipe 94 may be connected to the suction side of the blowing device 91. Then, the cooling gas exhausted through the exhaust pipe 94 may not be discharged to a factory exhaust system, but may be returned to the blowing device 91 after undergoing heat exchange in the heat exchanger 95 for use in circulation. In that case, it may be circulated through an air filter (not illustrated). The cooling gas discharged from the space 64 may be discharged from the exhaust pipe 94 to the factory exhaust system by way of the heat exchanger 95.

The blowing device 91 is configured to be able to control the cooling of the inside of the processing container 65 using power (RCU power), which is an output signal from a power supply 91a. For example, the power supply 91a including an inverter may control the air volume of the blowing device 91 by controlling the RCU power supplied to the blowing device 91 in response to a control signal from the control unit 100.

The control unit 100 is implemented by, for example, a computer 500 to be described later. The control unit 100 reads a program recorded in a storage device, and sends a control signal to each component constituting the heat treatment apparatus 10 to execute heat treatment according to the program. For example, the control unit 100 adjusts the temperature inside the processing container 65 by controlling the power supplied to the heater 63 and the blowing device 91 based on the temperature measured by the processing container internal temperature sensor Ai and a set temperature included in a recipe.

For example, control using a temperature model, called MBTC, is performed in the heat treatment apparatus 10 to alleviate the influence of a machine difference on temperature behavior. In model-based temperature control (MBTC), control is performed to absorb the machine difference by adjusting the heater power and RCU power for each heat treatment apparatus 10 and to achieve as consistent temperature behavior as possible among different heat treatment apparatuses 10.

Although MBTC may absorb the machine difference among the heat treatment apparatuses 10, MBTC is feedback control and therefore, a difference in temperature behavior occurs when the machine difference is significant, such as at the initial stage of control. Further, continuously operating with MBTC to absorb the machine difference existing among the heat treatment apparatuses 10 may potentially lead to a decrease in the lifespan of components and damage to the components. For example, the heat treatment apparatus 10 operated with a cracked insulation material requires greater heater power than the heat treatment apparatus 10 with an intact insulation material, which may potentially lead to a decrease in the lifespan of heater elements.

Therefore, in the embodiment, discrepancies between an actual machine and an ideal virtual model are ascertained by comparing time series data regarding the temperature behavior of the virtual model (ideal virtual model of the heat treatment apparatus 10), which is faithful to design information of the heat treatment apparatus 10, with time series data regarding the temperature behavior of the heat treatment apparatus 10 as the actual machine. The time series data regarding the temperature behavior are, for example, time series data on the heater power, RCU power, and measured temperature inside the processing container 65. In the embodiment, parameters of the ideal virtual model are adjusted (optimized) to minimize the sum of squares of difference data between the time series data regarding the temperature behavior of the ideal virtual model of the heat treatment apparatus 10 and the time series data regarding the temperature behavior of the heat treatment apparatus 10 as the actual machine.

Since the ideal virtual model is faithful to the design information, it can be said that the larger the rate of change in the parameter due to adjustment (optimization), the more the parameter deviates from the ideal state of the heat treatment apparatus 10. In other words, the greater the rate of change in the parameter of the virtual model due to adjustment (optimization), the more likely the parameter is to be a machine difference candidate.

The operator may investigate a location of the actual machine corresponding to the parameter of the virtual model identified as the machine difference candidate and may eliminate defects and problems, thereby fundamentally reducing the machine difference among the heat treatment apparatuses 10. Therefore, according to the embodiment, the machine difference among the heat treatment apparatuses 10 at the initial stage of control is reduced, making it easier to match dynamic temperature behavior. Further, according to the embodiment, a component with low health (component with degraded performance) may be identified and replaced based on the parameter identified as the machine difference candidate, which may prevent the component with low health from causing degradation and damage to other components.

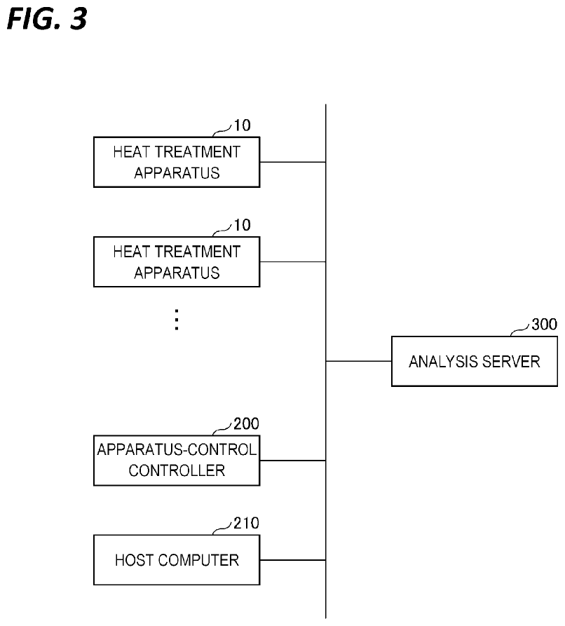

FIG. 3 is a diagram illustrating an example of a configuration of an information processing system according to the embodiment. The information processing system of FIG. 3 includes the heat treatment apparatus 10, an apparatus-control controller 200, a host computer 210, and an analysis server 300.

The heat treatment apparatus 10, apparatus-control controller 200, host computer 210, and analysis server 300 are interconnected to enable communication therebetween via a network such as a Local Area Network (LAN).

The heat treatment apparatus 10 executes a process in response to a control command (recipe) output from the apparatus-control controller 200. The apparatus-control controller 200 is a controller having a computer configuration for controlling the heat treatment apparatus 10. The apparatus-control controller 200 outputs control commands, used to control control components of the heat treatment apparatus 10, to the heat treatment apparatus 10.

The host computer 230 is an example of a man-machine interface (MMI) that receives instructions regarding the heat treatment apparatus 10 from the operator and provides information regarding the heat treatment apparatus 10 to the operator. The analysis server 300 identifies the machine difference candidate parameter from the parameters of the ideal virtual model, as described later. The ideal virtual model is created based on, e.g., the apparatus dimensions and physical property data of the heat treatment apparatus 10, and models a relationship of heat exchange, specific heat, and others.

Further, the analysis server 300 may display on, for example, the host computer 230, the identified machine difference candidate parameter, the component of the heat treatment apparatus 10 corresponding to the identified machine difference candidate parameter, or correspondence to the identified machine difference candidate parameter to allow the operator to confirm it.

In addition, it goes without saying that the information processing system of FIG. 3 is merely one example, and there are various system configuration examples depending on the applications and purposes thereof. The categorization of devices such as the heat treatment apparatus 10, apparatus-control controller 200, host computer 210, and analysis server 300 illustrated in FIG. 3 is merely one example.

For example, the information processing system may have various configurations, such as an integrated configuration of at least two of the heat treatment apparatus 10, apparatus-control controller 200, host computer 210, and analysis server 300, or a further divided configuration. The analysis server 300 is an example of an information processing apparatus that identifies a machine difference in the heat treatment apparatus 10. The information processing apparatus that identifies the machine difference in the heat treatment apparatus 10 may be implemented by the control unit 100, apparatus-control controller 200, or host computer 210.

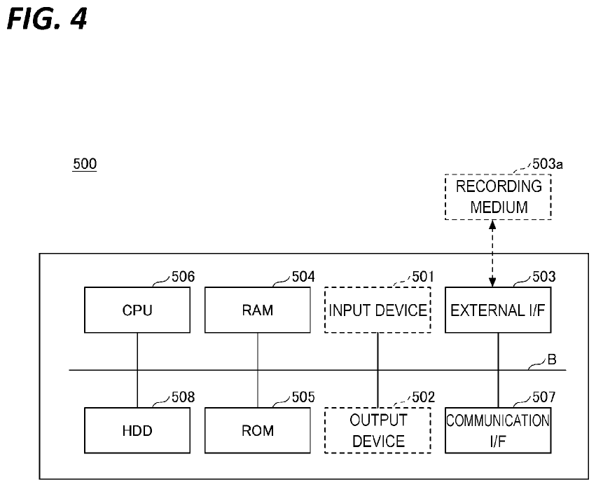

The apparatus-control controller 200, host computer 210, and analysis server 300 of the information processing system illustrated in FIG. 3 are implemented by, for example, a computer having a hardware configuration as illustrated in FIG. 4. Further, the control unit 100 of the heat treatment apparatus 10 illustrated in FIGS. 1 and 2 is implemented by, for example, a computer having the hardware configuration illustrated in FIG. 4. FIG. 4 is a diagram illustrating an example of a hardware configuration of a computer.

The computer 500 of FIG. 4 includes an input device 501, an output device 502, an external interface (I/F) 503, a random access memory (RAM) 504, a read only memory (ROM) 505, a central processing unit (CPU) 506, a communication I/F 507, and a hard disk drive (HDD) 508, among others, each of which is interconnected via a bus B. In addition, the input device 501 and the output device 502 may be connected and used as needed.

The input device 501 is a keyboard, mouse, touch panel or the like, and is used by the operator or others to input each operation signal. The output device 502 is a display or the like, and displays the processing results by the computer 500. The communication I/F 507 is an interface that connects the computer 500 to a network. The HDD 508 is an example of a non-volatile storage device that stores programs and data.

The external I/F 503 is an interface for an external device. The computer 500 may perform reading and/or writing on a recording medium 503a such as a secure digital (SD) memory card via the external I/F 503. The ROM 505 is an example of a non-volatile semiconductor memory (storage device) in which programs and data are stored. The RAM 504 is an example of a volatile semiconductor memory (storage device) that temporarily holds programs and data.

The CPU 506 is an arithmetic device that reads programs and data from a storage device such as the ROM 505 or the HDD 508 onto the RAM 504 and executes a processing, thereby realizing the overall control and functions of the computer 500.

The apparatus-control controller 200, host computer 210, and analysis server 300 of the information processing system illustrated in FIG. 3 may implement various functions by the computer 500 having the hardware configuration illustrated in FIG. 4. Further, the control unit 100 of the heat treatment apparatus 10 illustrated in FIGS. 1 and 2 may implement various functions by the computer 500 having the hardware configuration illustrated in FIG. 4.

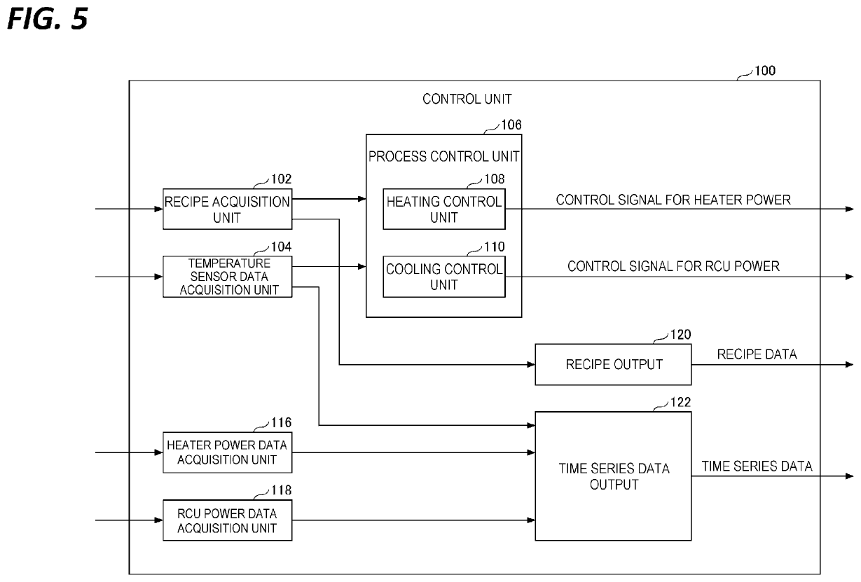

The control unit 100 of the heat treatment apparatus 10 is implemented by, for example, a functional configuration illustrated in FIG. 5. FIG. 5 is a diagram illustrating an example of a functional configuration of the control unit of the heat treatment apparatus according to the embodiment. In addition, in the functional block diagram of FIG. 5, the illustration of unnecessary components for the description of the embodiment is omitted.

The control unit 100 implements, through program execution, a recipe acquisition unit 102, temperature sensor data acquisition unit 104, process control unit 106, heating control unit 108, cooling control unit 110, heater power data acquisition unit 116, RCU power data acquisition unit 118, recipe output 120, and time series data output 122.

The recipe acquisition unit 102 acquires a recipe for a process to be executed by the heat treatment apparatus 10. The recipe acquisition unit 102 provides data of the acquired recipe (recipe data) to the process control unit 106. The recipe data include a set temperature inside the processing container 65. Further, the recipe acquisition unit 102 provides the recipe data to the recipe output 120.

The temperature sensor data acquisition unit 104 acquires measured temperature data, which are time series data of the heater temperature sensor Ao (Outer T/C) and the processing container internal temperature sensor Ai (Inner T/C). The temperature sensor data acquisition unit 104 provides the measured temperature data to the process control unit 106 and the time series data output 122.

The process control unit 106 executes a process in the heat treatment apparatus 10 according to the recipe provided from the recipe acquisition unit 102. The process control unit 106 includes the heating control unit 108 and the cooling control unit 110. The heating control unit 108 determines the heater power supplied from the heater output 86 to the heater 63 based on the provided set temperature and measured temperature inside the processing container 65. The heating control unit 108 controls the heater power supplied from the heater output unit 86 to the heater 63 by providing a control signal for the heater power to the heater output 86.

The cooling control unit 110 determines the RCU power supplied from the power supply 91a to the blowing device 91 based on the provided set temperature and measured temperature inside the processing container 65. The cooling control unit 110 controls the RCU power supplied from the power supply 91a to the blowing device 91 by providing a control signal for the RCU power to the power supply 91a.

The heater power data acquisition unit 116 acquires time series data on the heater power supplied from the heater output 86 to the heater 63, and provides the data, as heater power data, to the time series data output 122. The RCU power data acquisition unit 118 acquires time series data on the RCU power supplied from the power supply 91a to the blowing device 91, and provides the data, as RCU power data, to the time series data output 122.

The recipe output 120 outputs the recipe data provided from the recipe acquisition unit 102 to the analysis server 300. Further, the time series data output 122 outputs, as time series data regarding the temperature behavior of the heat treatment apparatus 10, the measured temperature data provided from the temperature sensor data acquisition unit 104, the heater power data provided from the heater power data acquisition unit 116, and the RCU power data provided from the RCU power data acquisition unit 118 to the analysis server 300.

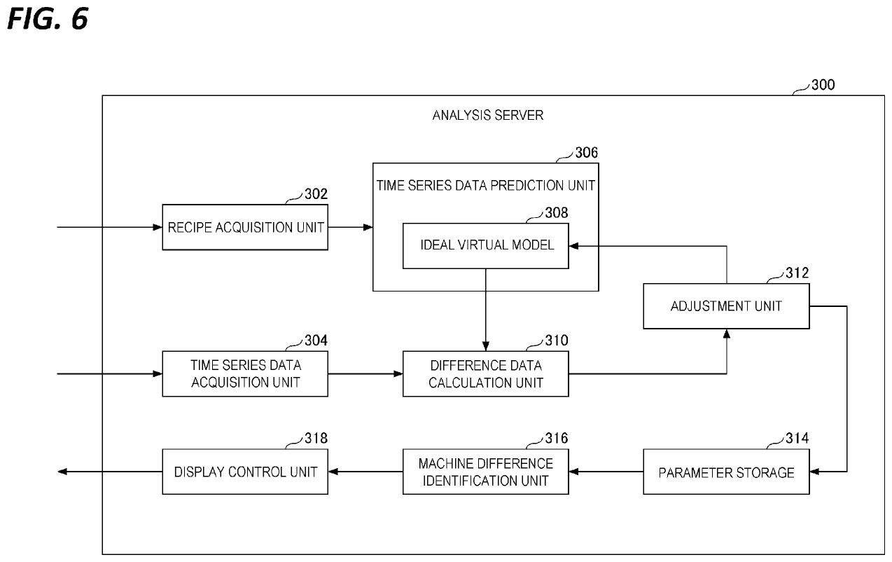

The analysis server 300 is implemented by, for example, a functional configuration illustrated in FIG. 6. FIG. 6 is a diagram illustrating an example of a functional configuration of an analysis server according to the embodiment. In addition, in the diagram of the functional configuration in FIG. 6, the illustration of unnecessary components for the description of the embodiment is omitted.

The analysis server 300 implements, through program execution, a recipe acquisition unit 302, time series data acquisition unit 304, time series data prediction unit 306, ideal virtual model 308, difference data calculation unit 310, adjustment unit 312, parameter storage 314, machine difference identification unit 316, and display control unit 318.

The recipe acquisition unit 302 acquires recipe data from a plurality of heat treatment apparatuses 10 that have executed a recipe. The recipe acquisition unit 302 provides the acquired recipe data to the time series data prediction unit 306. The time series data prediction unit 306 predicts time series data regarding the temperature behavior of the heat treatment apparatus 10 that has executed the recipe by executing the recipe data acquired from the heat treatment apparatus 10 in the ideal virtual model 308. The time series data regarding the temperature behavior of the heat treatment apparatus 10 predicted by the time series data prediction unit 306 include measured temperature data, heater power data, and RCU power data. As such, the time series data prediction unit 306 uses the ideal virtual model 308 to predict the time series data regarding the temperature behavior of the heat treatment apparatus 10 that has executed the recipe.

The time series data acquisition unit 304 acquires time series data regarding the temperature behavior of the heat treatment apparatus 10 from the plurality of heat treatment apparatuses 10 that have executed the recipe. The difference data calculation unit 310 calculates, for each heat treatment apparatus 10, difference data between the time-series data regarding the temperature behavior of the heat treatment apparatus 10 acquired from the heat treatment apparatus 10 and the time series data regarding the temperature behavior of the heat treatment apparatus 10 predicted by the time series data prediction unit 306.

Specifically, the difference data calculation unit 310 calculates, for each heat treatment apparatus 10, difference data between time-series data regarding the heater power of the heat treatment apparatus 10, which is acquired from the heat treatment apparatus 10 by the time series data acquisition unit 304, and time series data on the heater power of the heat treatment apparatus 10 predicted by the time-series data prediction unit 306.

The difference data calculation unit 310 calculates, for each heat treatment apparatus 10, difference data between time-series data of the RCU power of the heat treatment apparatus 10, which is acquired from the heat treatment apparatus 10 by the time series data acquisition unit 304, and time series data on the RCU power of the heat treatment apparatus 10 predicted by the time-series data prediction unit 306.

The difference data calculation unit 310 calculates, for each heat treatment apparatus 10, difference data between time-series data of the measured temperature of the heat treatment apparatus 10, which is acquired from the heat treatment apparatus 10 by the time series data acquisition unit 304, and time series data on the measured temperature of the heat treatment apparatus 10 predicted by the time-series data prediction unit 306.

The adjustment unit 312 adjusts, for each heat treatment apparatus 10, parameters of the ideal virtual model 308 so that the difference data for each heat treatment apparatus 10 calculated by the difference data calculation unit 310 becomes smaller. The adjustment unit 312 uses the difference data for each heat treatment apparatus 10 to adjust the parameters of the ideal virtual model 308 for each heat treatment apparatus 10. As such, the adjustment unit 312 adjusts (optimizes) the parameters of the ideal virtual model 308 so that time series data regarding the temperature behavior of the heat treatment apparatus 10 executing the same recipe and time series data regarding the temperature behavior of the ideal virtual model 308 are assimilated.

The parameter storage 314 stores, for each heat treatment apparatus 10, the parameters of the ideal virtual model 308 before and after adjustment by the adjustment unit 312. The machine difference identification unit 316 identifies the machine difference candidate parameter among the parameters of the ideal virtual model 308 based on a change in the parameters of the ideal virtual model 308 before and after adjustment as follows.

For example, the machine difference identification unit 316 may prioritize a parameter with a significant change before and after adjustment among the parameters of the ideal virtual model 308 to identify it as the machine difference candidate. Further, the machine difference identification unit 316 may identify a machine difference candidate parameter of first and second heat treatment apparatuses 10 based on a difference between the rate of change in the parameter of the first heat treatment apparatus 10 before and after adjustment and the rate of change in the parameter of the second heat treatment apparatus 10 before and after adjustment. The first heat treatment apparatus 10 may be a reference machine, which is a reference heat treatment apparatus 10. Further, the second heat treatment apparatus 10 may be a comparison machine, which is a heat treatment apparatus 10 compared to the reference machine.

The display control unit 318 displays on, for example, the host computer 230, the machine difference candidate parameter identified by the machine difference identification unit 316. The display control unit 318 may also display on, for example, the host computer 230, the component of the heat treatment apparatus 10 corresponding to the machine difference candidate parameter identified by the machine difference identification unit 316, or the correspondence to the identified machine difference candidate parameter.

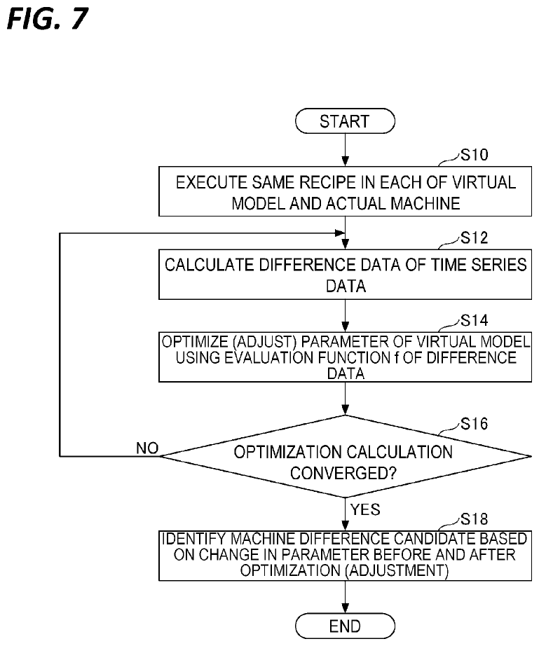

FIG. 7 is a flowchart illustrating an example of a processing procedure of the information processing system according to the embodiment. Here, an example of identifying the machine difference candidate parameter between the first heat treatment apparatus 10 (hereinafter referred to as reference machine) and the second heat treatment apparatus 10 (hereinafter referred to as comparison machine), both of which are actual machines, will be described.

In step S10, the reference machine, comparison machine, and ideal virtual model 308 execute a process according to the same recipe. The analysis server 300 acquires time series data of measured temperature data, heater power data, and RCU power data from the reference machine and the comparison machine that have executed the same recipe. Further, the analysis server 300 predicts time series data of the measured temperature data, heater power data, and RCU power data from the reference machine and the comparison machine by executing, in the ideal virtual model 308, the same recipe as that in the reference machine and the comparison machine.

In step S12, the analysis server 300 calculates difference data for each time series data of the measured temperature data, heater power data, and RCU power data between the reference machine and the ideal virtual model 308. Further, the analysis server 300 calculates difference data for each time series data of the measured temperature data, heater power data, and RCU power data between the comparison machine and the ideal virtual model 308.

In addition, the difference data for the measured temperature data, heater power data, and RCU power data calculated in step S12 may be preprocessed such as by standardization and be adjusted to equalize the influence in the evaluation function f(p) to be described later.

In step S14, the analysis server 300 uses, as the evaluation function f(p), the sum of squares of the difference data as follows. The variable of the evaluation function f(p) is the difference data d for the measured temperature data, heater power data, and RCU power data. The analysis server 300 optimizes (adjusts) the parameters of the ideal virtual model 308 to minimize the evaluation function f(p).

$$f ( p ) = {\sum }_{t} {\sum }_{i} {d}_{i}^{2} \qquad ( Equation 1 )$$

ρ: parameter vector, d: difference data,
i: subscript representing each variable, t: time

In step S16, the analysis server 300 determines whether the optimization calculation in step S14 has converged. The analysis server 300 repeats a processing of steps S12 to S16 until it determines that the optimization calculation in step S14 has converged. Through the processing of steps S12 to S16, the analysis server 300 may optimize (adjust) the parameters of the ideal virtual model 308 to assimilate the ideal virtual model 308 to the state of the reference machine executing the same recipe. Further, through the processing of steps S12 to S16, the analysis server 300 may optimize (adjust) the parameters of the ideal virtual model 308 to assimilate the ideal virtual model 308 to the state of the comparison machine executing the same recipe.

The processing of steps S14 and S16 may be performed in various ways, such as using the gradient of the evaluation function f(p), using genetic algorithms, and using Bayesian optimization. In the use of the gradient of the evaluation function f(p), the steepest descent method, Newton method, quasi-Newton method, and other methods may be used. The analysis server 300 updates the solution according to the gradient of the evaluation function f(p), and outputs, as an optimal solution, the solution when a change in the solution or a change in the gradient (degree of solution update) becomes smaller than a threshold value (convergence criterion) determined before learning. Further, in the use of genetic algorithms, among N randomly generated solutions, by selecting several solutions that represent good values of the evaluation function f(p) (selectivity) and changing the values of these solutions to different values (mutation) or exchanging the solutions with each other (crossover), more suitable solutions are searched while maintaining the goodness of the solutions. In the use of Bayesian optimization, there are two representative stochastic models: the Gaussian process approach, which uses Gaussian process regression as a black box surrogate function; and the Tree-structured Parzen estimator (TPE) approach, which assumes that all hyperparameters are independent and estimates the probability density function by kernel density estimation. In the Gaussian process approach, the variance-covariance matrix is obtained from the kernel function and observed data to estimate the mean and variance at unknown points. Subsequently, the point with the maximum acquisition function is set to the next search point and the observed value at that point is examined. The acquisition function is given by the mean and variance of the surrogate function. By using this mean, the acquired observed values may be utilized, while the variance allows for the search of unknown points. Meanwhile, the TPE approach estimates the probability density function of the parameters in score high-rank and low-rank groups by kernel density estimation, and determines the next search point from the density ratio of the two groups. Further, the use of an optimization method called multi-task Bayesian optimization, which transfers the characteristics of one optimization problem to the characteristics of another similar optimization problem to construct a highly accurate surrogate model even with a small number of data points and efficiently search for the optimal solution, is also considered effective for parameter optimization during actual model operation.

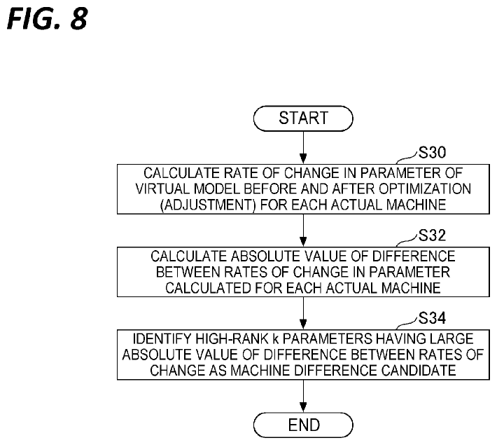

When it is determined that the optimization calculation in step S14 has converged, in step S18, the analysis server 300 identifies a machine difference candidate based on a change in parameters before and after optimization (adjustment), for example, as illustrated in FIG. 8.

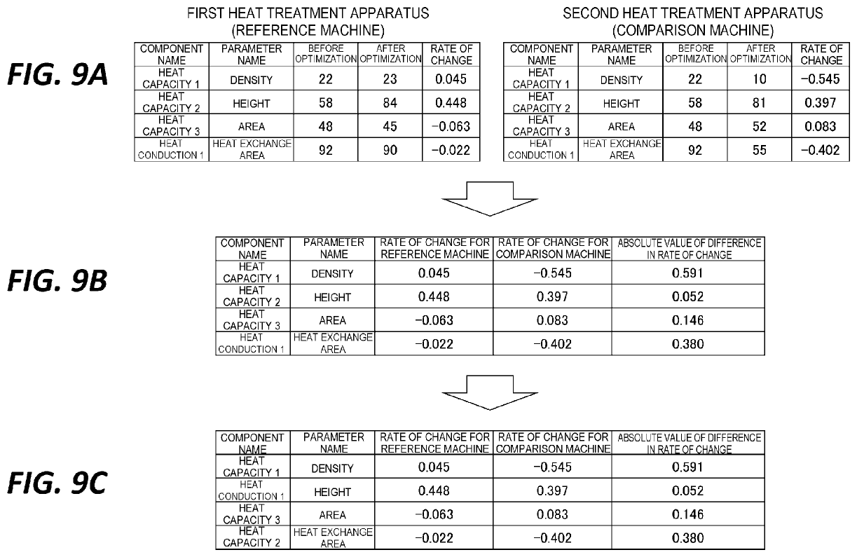

FIG. 8 is a flowchart illustrating an example of a processing procedure of identifying a machine difference candidate. FIGS. 9A to 9C are diagrams illustrating an example of a processing of identifying a machine difference candidate. FIGS. 9A to 9C illustrate an example for four parameters of the virtual model 308, but the number of parameters may be other than four.

In step S30, the analysis server 300 calculates the rate of change in the parameters of the ideal virtual model 308 before and after optimization (adjustment) for each of the reference machine and the comparison machine. The rate of change CR in the parameters of the ideal virtual model 308 before and after optimization (adjustment) may be calculated by the following equation:

$$CR = ( ( {p}_{opt} - {p}_{before} ) / {p}_{before} )$$

p_{before} is the parameter before optimization (adjustment). Further, pₒₚₜ is the parameter after optimization (adjustment). Here, pₒₚₜ is expressed by the following equation.

$${p}_{opt} = arg min {\sum }_{p} f ( p ) \qquad ( Equation 2 )$$

pₒₚₜ: parameter vector after optimization
f(p): evaluation function

In the processing of step S30, for example, as illustrated in FIG. 9A, the rate of change in the parameters of the ideal virtual model 308 before and after optimization (adjustment) is calculated for each of the reference machine and the comparison machine.

In addition, in FIG. 9A, the parameters of the ideal virtual model 308 are illustrated, by way of example, as Density of Component Name “Heat Capacity 1,” Height of Component Name “Heat Capacity 2,” Area of Component Name “Heat Capacity 3,” and Heat Exchange Area of Component Name “Heat Conduction 1,” but may also be, for example, position, contact heat resistance, contact heat conductance, gain, and others.

In step S32, the analysis server 300 calculates the absolute value of a difference between the rates of change in the parameters of the ideal virtual model 308 before and after optimization (adjustment) calculated for each of the reference machine and the comparison machine in step S30. In the processing of step S32, for example, the absolute value of the difference between the rates of change of each parameter may be calculated, as illustrated in FIG. 9B. In FIG. 9B, the rate of change in the parameters before and after optimization (adjustment) of the ideal virtual model 308 that has been optimized (adjusted) to assimilate to the state of the reference machine is described as “Rate of Change in Reference Machine.” Further, in FIG. 9B, the rate of change in the parameters before and after optimization (adjustment) of the ideal virtual model 308 that has been optimized (adjusted) to assimilate to the state of the comparison machine is described as “Rate of Change in Comparison Machine.”

In step S34, the analysis server 300 identifies the high-rank k parameters, for which the absolute value of the difference in the rate of change of the parameters of the ideal virtual model 308 before and after optimization (adjustment) calculated in step S32 is large, as machine difference candidate parameters. In the processing of step S34, for example, as illustrated in FIG. 9C, the parameters of the ideal virtual model 308 are sorted in descending order of the absolute value of the difference in the rate of change, and the high-rank k parameters may be identified as the machine difference candidate parameters.

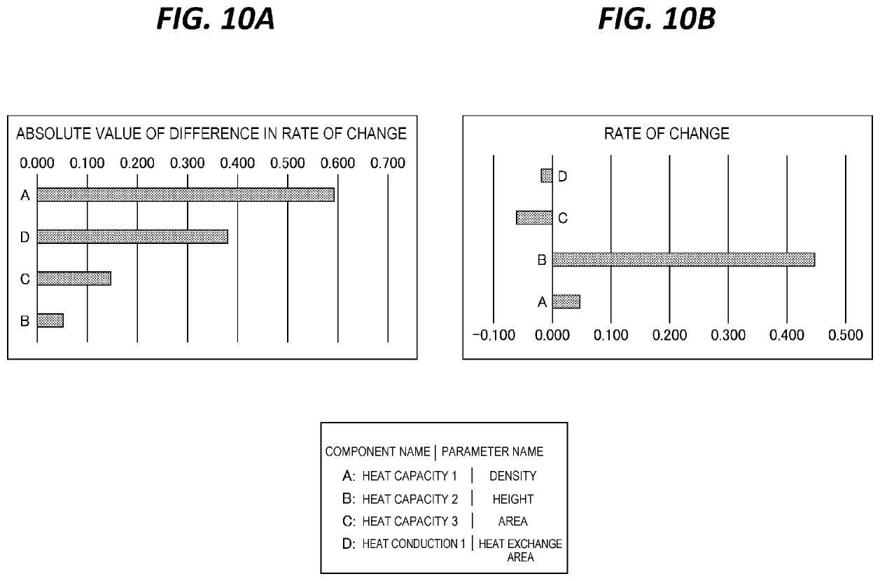

The analysis server 300 may present the results sorted in step S34 to the operator by displaying the results, for example, as illustrated in FIG. 10A. FIGS. 10A and 10B are diagrams illustrating an example of a display image presented to the operator.

FIG. 10A is a graph illustrating the absolute value of the difference in the rate of change in the parameters of the ideal virtual model 308 in descending order of the absolute value of the difference in the rate of change. The operator referring to the graph in FIG. 10A may identify the parameter “A: Density of Heat Capacity 1” of the ideal virtual model 308 as a first machine difference candidate between the reference machine and the comparison machine. Further, the operator referring to the graph in FIG. 10A may identify the parameter “D: Heat Exchange Area of Heat Conduction 1” of the ideal virtual model 308 as a second machine difference candidate between the reference machine and the comparison machine.

The analysis server 300 may present to the operator the rate of change in the parameters of the ideal virtual model 308 before and after optimization (adjustment) calculated for each of the reference machine and the comparison machine in step S30, for example, by displaying it as illustrated in FIG. 10B. FIG. 10B is a graph illustrating the rate of change in the parameters of the ideal virtual model 308 before and after optimization (adjustment) calculated for the reference machine. The operator referring to the graph in FIG. 10B may determine a difference in the state between the reference machine and the ideal virtual model 308 based on the rate of change in the parameters before and after optimization (adjustment). For example, the operator referring to the graph in FIG. 10B may determine the parameter “B: Height of Heat Capacity 2” having the largest difference as the difference in the state between the reference machine and the ideal virtual model 308.

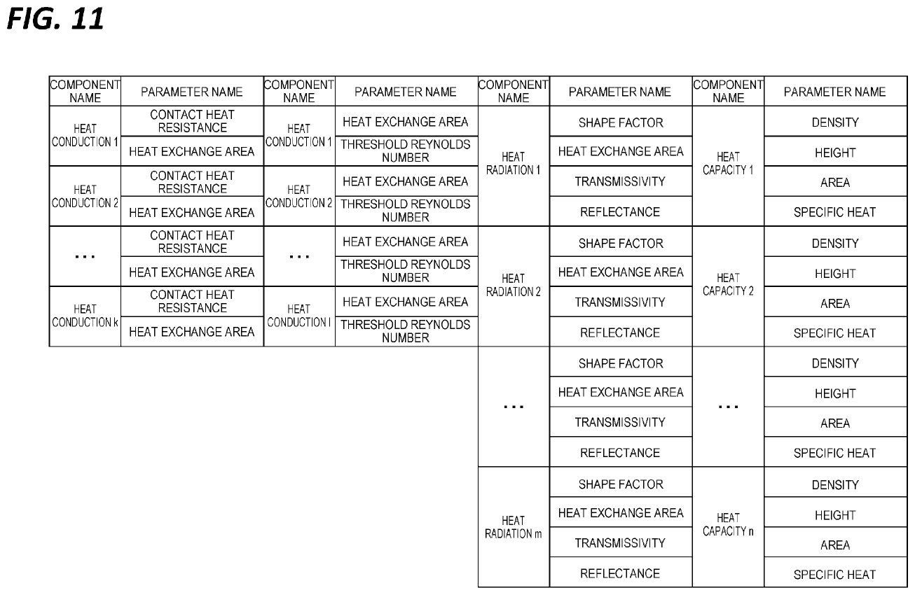

In addition, the analysis server 300 may use a table as illustrated in FIG. 11, for example, to display on, for example, the host computer 230, components corresponding to the machine difference candidate parameters to allow the operator to confirm the components. FIG. 11 is a diagram illustrating an example of a configuration of a table that corresponds the parameters of an ideal virtual model to components of the heat treatment apparatus.

For example, in the case of 1D-CAE simulation software, where a parameter that may be set for each component is determined, the table as illustrated in FIG. 11 may be created by utilizing the parameter that may be set for each component. For example, when the parameter “Density” of the component “Heat Capacity 1” is identified as a first machine difference candidate between the reference machine and the comparison machine, the analysis server 300 may present the component “Heat Capacity 1” to the operator.

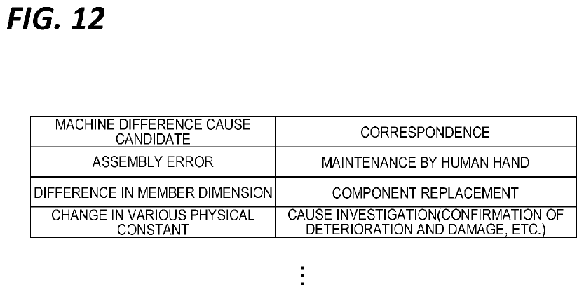

Further, the analysis server 300 may use a table as illustrated in FIG. 12, for example, to display on, for example, the host computer 230, correspondence to the machine difference cause candidate to allow the operator to confirm it. FIG. 12 is a diagram illustrating an example of a configuration of a table that corresponds correspondence to a machine difference cause candidate.

For example, a relationship between the machine difference cause candidate and the correspondence to the cause candidate may be set in the table of FIG. 12 based on the operator's idea, or may be automatically created based on data accumulated through continued operation.

In the embodiment, the parameters of an ideal virtual model are optimized (adjusted) to minimize difference data between time series data regarding the temperature behavior of an actual machine executing the same recipe and time series data regarding the temperature behavior predicted by an ideal virtual model, so that the virtual model 308 is optimized (adjusted) to assimilate to the state of the actual machine.

The larger the rate of change in the parameter of the virtual model 308 that has been assimilated to the state of the actual machine before and after optimization (adjustment), the more the parameter can be said to deviate from the ideal state of the heat treatment apparatus 10, so that the parameter may be used to identify the machine difference candidate in the heat treatment apparatus 10.

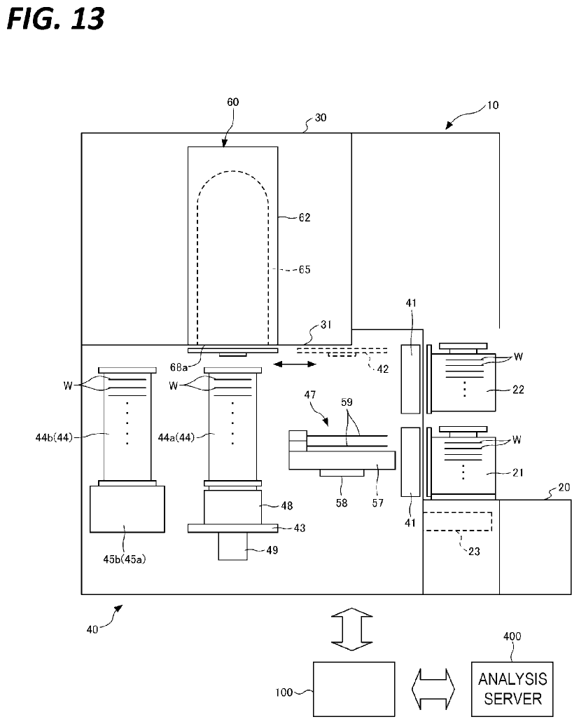

The information processing system according to the embodiment may identify a machine difference candidate in the heat treatment apparatus 10 by utilizing digital twin technology. In the above-described embodiment, the analysis server 300 was responsible for identifying the machine difference candidate in the heat treatment apparatus 10. The processing of identifying the machine difference candidate in the heat treatment apparatus 10 may be executed by the control unit 100 of the heat treatment apparatus 10, apparatus-control controller 200, or host computer 210. Further, the processing of identifying the machine difference candidate in the heat treatment apparatus 10 may be executed by an analysis server part 400 of the heat treatment apparatus 10 as illustrated in FIG. 13. FIG. 13 is a longitudinal cross-sectional view schematically illustrating the heat treatment apparatus according to the embodiment. The heat treatment apparatus 10 of FIG. 13 includes the analysis server part 400, in addition to the configuration of FIG. 1. The analysis server part 400 performs the same processing as the analysis server 300.

In addition, it goes without saying that the above information processing system is merely one example, and there are various system configuration examples depending on the applications and purposes. For example, the information processing system may have various configurations, such as an integrated configuration of at least two of the heat treatment apparatus 10, apparatus-control controller 200, host computer meter 210, and analysis server 300, or a further divided configuration.

According to the present disclosure, it is possible to identify a machine difference candidate in a heat treatment apparatus using an ideal virtual model of the heat treatment apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus, the information processing apparatus comprising:
a time series data acquisition circuitry configured to acquire time series data regarding temperature behavior of a plurality of heat treatment apparatuses that have executed a recipe;
a time series data prediction circuitry configured to predict time series data regarding temperature behavior of each of the plurality of heat treatment apparatuses that has executed the recipe, using an ideal virtual model of the heat treatment apparatus;
a difference data calculation circuitry configured to calculate difference data between the acquired time series data and the predicted time series data for each of the plurality of heat treatment apparatuses;
an adjustment circuitry configured to adjust a parameter of the virtual model for each of the plurality of heat treatment apparatuses, using the difference data; and
a machine difference identification circuitry configured to identify a machine difference candidate parameter based on a change in the parameter before and after adjustment for each of the plurality of heat treatment apparatuses.

2. The information processing apparatus according to claim 1, wherein the machine difference identification circuitry is configured to give priority to identifying a parameter with a larger change before and after adjustment as the machine difference candidate parameter among two heat treatment apparatuses of the plurality of heat treatment apparatuses.

3. The information processing apparatus according to claim 1, wherein the adjustment circuitry is configured to adjust the parameter of the virtual model so as to minimize difference data between time series data regarding temperature behavior of a first heat treatment apparatus and the predicted time series data, and to adjust the parameter of the virtual model so as to minimize difference data between time series data regarding temperature behavior of a second heat treatment apparatus and the predicted time series data, and
the machine difference identification circuitry is configured to identify the machine difference candidate parameter based on a difference between a rate of change in the parameter of the first heat treatment apparatus before and after adjustment and a rate of change in the parameter of the second heat treatment apparatus before and after adjustment.

4. The information processing apparatus according to claim 1, further comprising a display control circuitry configured to display a component of the heat treatment apparatus corresponding to the machine difference candidate parameter identified by the machine difference identification circuitry.

5. The information processing apparatus according to claim 1, further comprising a display control circuitry configured to display correspondence to the machine difference candidate parameter identified by the machine difference identification circuitry.

6. The information processing apparatus according to claim 1, wherein the time series data regarding the temperature behavior of the heat treatment apparatus includes time series data on power supplied to a heater that heats an inside of a processing container accommodating the processing target substrate, time series data on power supplied to a cooler that cools the inside of the processing container, and time series data on a measured temperature inside the processing container.

7. A method for identifying a machine difference, the method being executed by an information processing apparatus that identifies a machine difference in a heat treatment apparatus for heat-treating a processing target substrate, the method comprising:
acquiring time series data regarding temperature behavior of a plurality of heat treatment apparatuses that have executed a recipe;
predicting time series data regarding temperature behavior of each of the plurality of heat treatment apparatuses that has executed the recipe, using an ideal virtual model of the heat treatment apparatus;
calculating difference data between the acquired time series data and the predicted time series data for each of the plurality of heat treatment apparatuses;
adjusting a parameter of the virtual model for each of the plurality of heat treatment apparatuses, using the difference data; and
identifying the machine difference candidate parameter based on a change in the parameter before and after adjustment for each of the plurality of heat treatment apparatuses.

8. A heat treatment apparatus for heat-treating a processing target substrate, comprising:
a time series data acquisition circuitry configured to acquire time series data regarding temperature behavior of a plurality of heat treatment apparatuses that have executed a recipe;
a time series data prediction circuitry configured to predict time series data regarding temperature behavior of each of the plurality of heat treatment apparatus that has executed the recipe, using an ideal virtual model of the heat treatment apparatuses;
a difference data calculation circuitry configured to calculate difference data between the acquired time series data and the predicted time series data for each of the plurality of heat treatment apparatuses;
an adjustment circuitry configured to adjust a parameter of the virtual model for each of the plurality of heat treatment apparatuses, using the difference data; and
a machine difference identification circuitry configured to identify the machine difference candidate parameter based on a change in the parameter before and after adjustment for each of the plurality of heat treatment apparatuses.
